(19) United States
(12) Patent Application Publication
(10) Pub. No.: US 2010/0232123 A1
(43) Pub. Date: Sep. 16, 2010

(54) Circuit interface device

(75) Inventor: Hui-Chen CHANG, Taipei (TW)

Correspondence Address: BACON & THOMAS, PLLC, 625 SLATERS LANE, FOURTH FLOOR, ALEXANDRIA, VA, 22314-1176, US

(73) Assignee: KYE SYSTEMS CORP., Taipei (TW)

(21) Appl. No.: 12/656,953

(22) Filed: Feb. 22, 2010

(30) Foreign Application Priority Data
Mar. 11, 2009 (TW) 098107939

(51) Int. Cl. H05K 5/00

(52) U.S. Cl. 361/752

(57) ABSTRACT

A circuit interface device includes a shell and a circuit board assembly. The circuit board assembly has a circuit board protection cap and a circuit board installed on the circuit board protection cap. A plurality of electrical connection contacts is disposed on one side surface of the circuit board. The circuit board assembly and the shell are assembled together in a structural matching mode. The circuit board is supported by the circuit board protection cap, so that the electrical connection contacts on the circuit board are corresponding to a socket at one end of the shell, and the shell enables the circuit interface device to be electrically inserted into a circuit interface jack of an electronic device by using a connecting portion.

### CROSS-REFERENCE TO RELATED APPLICATIONS

This non-provisional application claims priority under 35 U.S.C. §119(a) on Patent Application No(s). 098107939 filed in Taiwan, R.O.C. on Mar. 11, 2009, the entire contents of which are hereby incorporated by reference.

### BACKGROUND OF THE INVENTION

1. Field of Invention

The present invention relates to a circuit interface device, and more particularly to a circuit interface device applied in an electronic device.

2. Related Art

Due to the advantages of hot plugging, plug-and-play, high transmission speed, and portability, universal serial bus (USB) transmission interfaces have been widely applied in various computer peripheral devices and consumer electronic products. For example, a USB flash drive or a wireless receiver uses a plug of a USB interface for being connected to an electrical jack in the USB specification of a computer. However, the USB flash drive and the wireless receiver both have the defect of an excessively large volume, and easily cause damages to the device and the computer due to accidental collision.

In order to eliminate the above defect, many innovations have been proposed in the relevant industry. For example, U.S. Pat. No. 7,165,998 has disclosed an improved structure of a USB compatible application apparatus, and the design concept is to reduce an overall length of the USB compatible application apparatus by using a double-layer circuit board, which further brings the following problem on the other hand. The electrical connection contacts of the USB compatible application apparatus are directly disposed on the circuit board and electrically connected to a computer USB jack directly through the circuit board. But the circuit board is assembled in a covering shell and has no supporting structure there-below, so that the circuit board is suspended, and thus the USB compatible application apparatus cannot be securely installed in the jack. Accordingly, U.S. Pat. No. 7,165,998 has designed a supporting structure and a front end protection layer for supporting the circuit board, and the connector needs to be wrapped by the covering shell.

In this way, although the above conventional USB compatible application apparatus reduces the overall volume through the design of the double-layer circuit board and further reduces the total length, the USB compatible application apparatus adopts a plurality of elements to support the circuit board, which results in a rather complex structure and causes difficulties in manufacturing and processing. Moreover, the supporting structure and the front end protection layer are assembled in the covering shell by means of gluing to achieve the tight bonding effect there-between, so that more labor time and labor work are consumed in assembly, which results in a complicated assembly process. In addition, since the USB compatible application apparatus is tightly adhered by gluing, it cannot be disassembled freely, and if the covering shell is disassembled, it may cause damages, and the USB compatible application apparatus cannot be used any more, which also imposes a heavy burden on maintenance.

According to the above patent, the Logitech International S.A. has launched a receiver for NANO cordless laser mouse for notebooks. The receiver of the Logitech International S.A. has a double-layer circuit board. One end of the double-layer circuit board is clamped by two plastic members, and the exposed double-layer circuit board is wrapped by a shell made of a metallic material, so as to constitute a receiver with a complete profile. However, since the receiver launched by the Logitech International S.A. adopts the plastic members and the shell made of the metallic material to completely wrap the circuit board, the manufacturing cost is increased, and different appearance designs, for example, using different materials and colors, cannot be realized, so that an appearance with desirable design cannot be provided depending upon the market demands.

### SUMMARY OF THE INVENTION

In view of the above problems, the present invention is a circuit interface device, which is applicable to solve the problems in the prior art that a USB compatible application apparatus has a complex structure and is assembled by gluing, or a metallic material is selected as the material for the components of the USB compatible application apparatus, which not only consumes more labor time but also causes difficulties in assembly to result in a complicated assembly process and increase the manufacturing cost.

The present invention provides a circuit interface device, which is applicable to an electronic device having a circuit interface jack. The circuit interface device comprises a shell and a circuit board assembly. A socket is disposed at one end of the shell. The circuit board assembly has a circuit board and a circuit board protection cap. The circuit board is disposed on the circuit board protection cap. A plurality of electronic components is arranged on two surfaces of the circuit board, and a plurality of electrical connection contacts is disposed on one side surface of the circuit board. The circuit board assembly is assembled in the shell. The circuit board protection cap enables the electrical connection contacts of the circuit board to be corresponding to the socket. The shell constitutes a connecting portion, and enables the circuit interface device to be inserted into the circuit interface jack through the connecting portion.

In the circuit interface device of the present invention, the circuit board assembly is assembled in the shell in a structural matching mode, so as to simplify operating procedures, and achieve rapid disassembly and assembly, which is quite convenient. Moreover, since the circuit interface device uses a few components and adopts simple assembly steps, the labor time cost for manufacturing and assembly can be reduced. In addition, since the circuit board protection cap in the present invention can effectively support the circuit board, the circuit interface device is securely corresponding to and located in the circuit interface jack of the electronic device, so that the stability of the circuit interface device is further enhanced.

Besides, one side of the circuit board protection cap is exposed to the exterior, which can satisfy various appearance requirements from the user and employ different materials and colors, so as to make the design of the circuit interface device more flexible. In addition, since the circuit board of the present invention adopts the configuration of a double-layer circuit board, the circuit board is shortened, and the overall volume of the circuit interface device is reduced.

### BRIEF DESCRIPTION OF THE DRAWINGS

The present invention will become more fully understood from the detailed description given herein below for illustration only, and thus are not limitative of the present invention, and wherein:

FIG. 1 is a schematic view of a circuit interface device and an electronic device according to an embodiment of the present invention;

FIG. 2 is an exploded view of a circuit interface device according to an embodiment of the present invention;

FIG. 3 is a schematic assembly view of a circuit interface device according to an embodiment of the present invention;

FIG. 4 is an exploded view of a circuit board assembly according to an embodiment of the present invention;

FIG. 5 is a schematic cross-sectional view of FIG. 3;

FIG. 6 is another schematic cross-sectional view of FIG. 3;

FIG. 7 is another schematic three-dimensional cross-sectional view of FIG. 3;

FIG. 8 is an exploded view of a circuit interface device according to another embodiment of the present invention;

FIG. 9 is an exploded view of a circuit board assembly according to another embodiment of the present invention; and

FIG. 10 is a schematic cross-sectional view of a circuit board assembly according to another embodiment of the present invention.

### DETAILED DESCRIPTION OF THE INVENTION

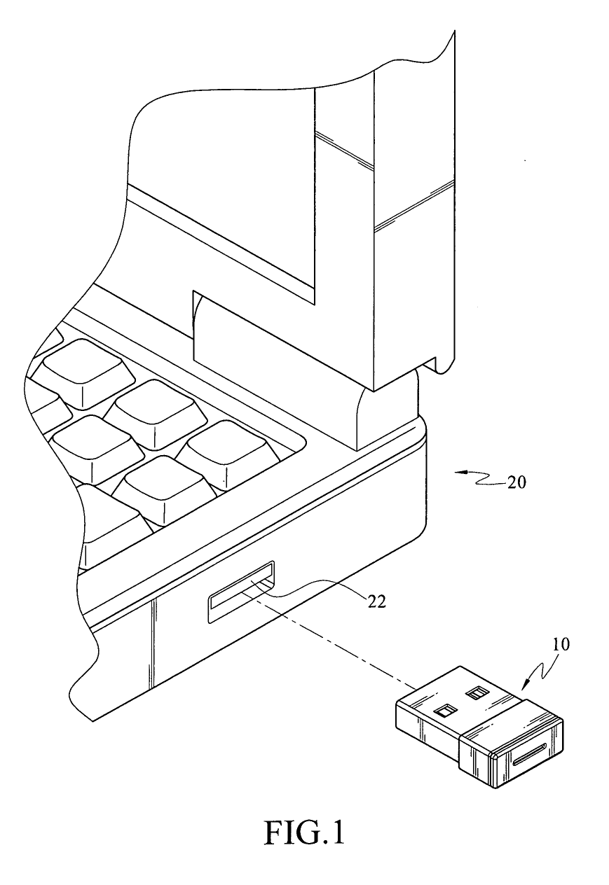

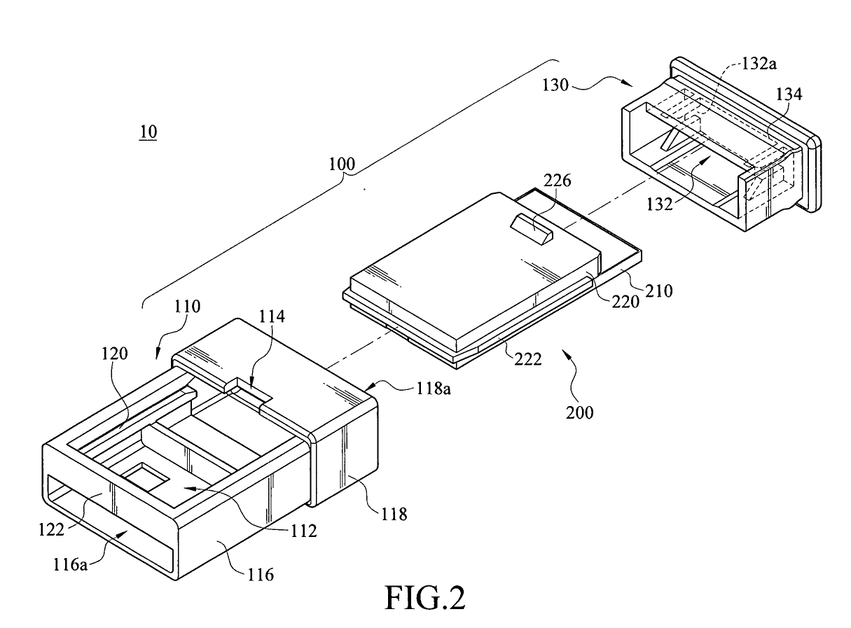

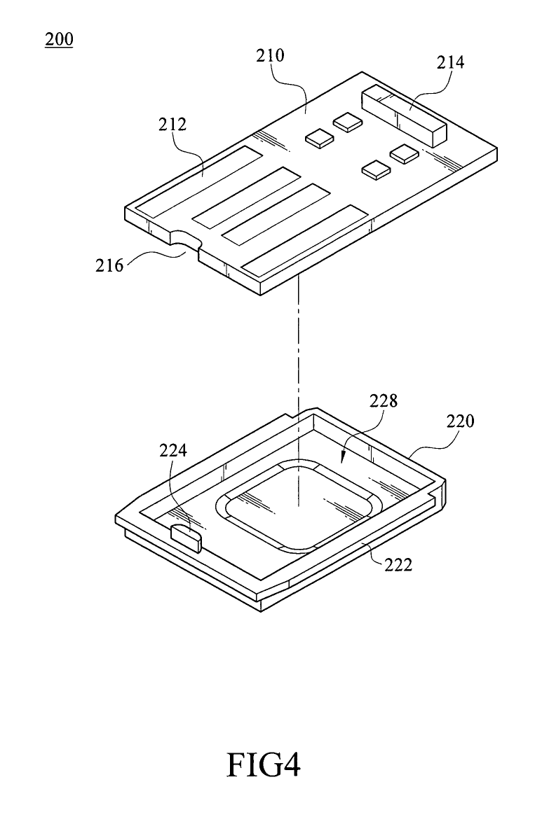

FIG. 1 is a schematic view of a circuit interface device and an electronic device according to an embodiment of the present invention. FIGS. 2 to 4 are schematic views of a circuit interface device according to an embodiment of the present invention. Referring to FIG. 1, a circuit interface device 10 in this embodiment is applied in an electronic device 20. The electronic device 20 has a circuit interface jack 22 provided for the circuit interface device 10 to be electrically inserted therein. In this embodiment, the electronic device 20 is for example, but not limited to, a notebook computer, a desktop computer, an ultra mobile personal computer (UMPC), or the like.

In the present invention, the so-called circuit interface refers to a connection interface conforming to the USB specification, and the circuit interface device 10 generally refers to a USB flash drive, a Bluetooth receiver, a radio frequency receiver, an infrared receiver, or other wireless receivers (DONGLE), as well as other circuit interface devices 10 conforming to the USB specification, which may also be applied to the IEEE1394, HDMI interface specification, etc. A USB interface is taken as the most preferred embodiment of the present invention in the following detailed description of the present invention. However, the accompanying drawings are merely provided for making reference and illustration, but not intended to limit the scope of the present invention.

Referring to FIGS. 2, 3, and 4, the circuit interface device 10 in this embodiment comprises a shell 100 and a circuit board assembly 200. The shell 100 comprises a shell body 110 and a shell cover 130. The circuit board assembly 200 is formed by a circuit board 210 and a circuit board protection cap 220. The circuit board assembly 200 is accommodated in the shell body 110, and one end of the shell cover 130 is assembled in the shell body 110.

The shell body 110 has a space for accommodating the circuit board assembly 200 therein, and the space in the shell body 110 must be slightly larger than an outer size of the circuit board assembly 200, such that the circuit board assembly 200 can be exactly accommodated in the shell body 110. In this embodiment, the shell body 110 may be made of, but not limited to, plastic, plastic steel, polymer, or other non-metallic materials.

The circuit board 210 is installed on the circuit board protection cap 220. A plurality of electronic components 214 is respectively arranged on two opposite side surfaces of the circuit board 210 to constitute a configuration of a double-sided circuit board, and a plurality of electrical connection contacts 212 is arranged on one of the side surfaces of the circuit board 210. A first positioning portion 216 is disposed at one end of the circuit board 210, and the profile of the first positioning portion 216 is, for example, a notch.

The circuit board protection cap 220 has a sliding block 222 and a second positioning portion 224. The sliding block 222 is disposed on a side edge of the circuit board protection cap 220. The second positioning portion 224 protrudes from a side surface of the circuit board protection cap 220 and is corresponding to the position of the first positioning portion 216. In this embodiment, the first positioning portion 216 and the second positioning portion 224 are complementary in profile, and the profile of the second positioning portion 224 is, for example, a bump, so as to match the first positioning portion 216 as a notch. In this way, through the shape matching between the first positioning portion 216 and the second positioning portion 224, the circuit board 210 can be fixed on the circuit board protection cap 220. Here, it should be noted that, the profiles and the combination mode of the first positioning portion 216 and the second positioning portion 224 are not limited in the present invention, so that in other embodiments according to the present invention, the first positioning portion 216 and the second positioning portion 224 may be combined in other forms.

An open slot 112 and a clipping slot 114 are opened on one outer side surface of the shell body 110. A clipping block 226 is protruded on a side surface of the circuit board protection cap 220 corresponding to the clipping slot 114. When the circuit board assembly 200 is installed in the shell body 110, the clipping block 226 of the circuit board protection cap 220 is clipped to the clipping slot 114 of the shell body 110, such that the circuit board assembly 200 is securely combined with the shell body 110 without falling off. In this way, since the clipping block 226 and the clipping slot 114 are fastened together to fix the circuit board assembly 200 with the shell body 110, the assembled circuit board assembly 200 and shell body 110 are prevented from sliding back and forth with respect to each other. Moreover, when the circuit board assembly 200 is installed in the shell body 110, one side surface of the circuit board protection cap 220 becomes coplanar with the outer side surface of the shell body 110, so that the side surface of the circuit board protection cap 220 may serve as the outer side surface of the shell body 110, i.e., the circuit board protection cap 220 covers the open slot 112. As known from the above, since the side surface of the circuit board protection cap 220 is used as the outer side surface of the shell body 110 and shields the open slot 112, the processing material of the shell body 110 during manufacturing can be saved, so as to reduce the manufacturing cost. In this embodiment, the circuit board protection cap 220 may be made of, for example, but not limited to, plastic, plastic steel, or a non-metallic material. Moreover, since one side of the circuit board protection cap 220 may be used as the outer side surface of the shell body 110, i.e., the side of the circuit board protection cap 220 is exposed to the exterior, the circuit board protection cap 220 may adopt different materials and colors according to different appearance requirements, so as to improve the appearance design of the circuit interface device 10 and enhance the competitiveness on the market.

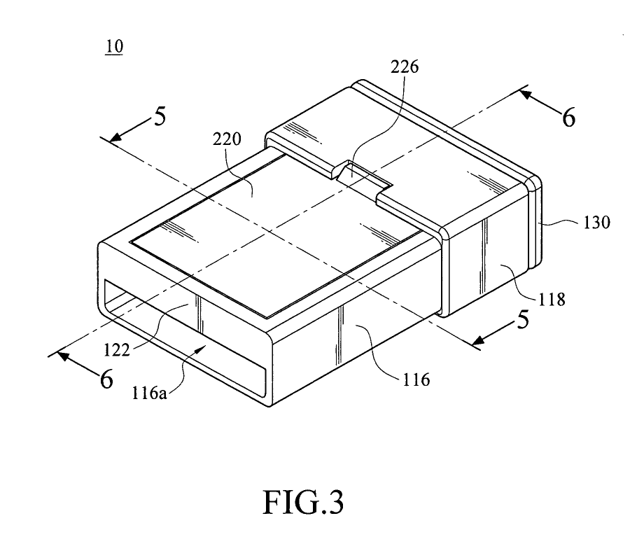

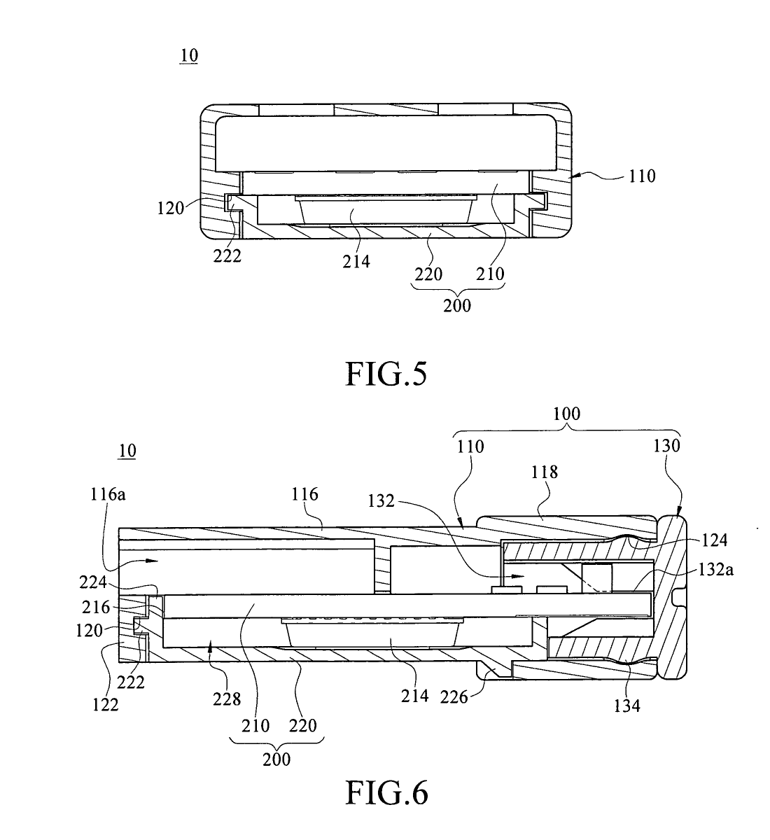

FIG. 5 is a schematic cross-sectional view of FIG. 3. Referring to FIGS. 1, 2, and 5, the shell body 110 comprises a connecting portion 116 and an end portion 118. A socket 116a is disposed at one side of the connecting portion 116. An opening 118a is opened at the end portion 118. The shell body 110 further has a first sliding slot 120 disposed on an inner side surface thereof, and the sliding block 222 is corresponding to the position of the first sliding slot 120 in the shell body 110. The circuit board protection cap 220 of the circuit board assembly 200 is slidably disposed in the first sliding slot 120 through the sliding block 222 and disposed in the shell body 110. In particular, when the circuit board assembly 200 is assembled in the shell body 110 via the opening 118a of the end portion 118, the circuit board assembly 200 is made to slide into the shell body 110 by enabling the sliding block 222 of the circuit board protection cap 220 to be corresponding to the position of the first sliding slot 120. An outer size of the sliding block 222 is smaller than the size of the first sliding slot 120, such that the sliding block 222 can smoothly slide into the first sliding slot 120 to further assemble the circuit board assembly 200 into the shell body 110.

In addition, when the circuit board assembly 200 is assembled in the shell body 110 via the opening 118a of the end portion 118, the circuit board 210 is supported by the circuit board protection cap 220, so that the electrical connection contacts 212 of the circuit board 210 are corresponding to the position of the socket 116a of the connecting portion 116. When the user inserts the connecting portion 116 of the circuit interface device 10 into the electronic device 20, the connecting portion 116 can be securely inserted in the circuit interface jack 22, and the electrical connection contacts 212 on the circuit board 210 are electrically connected to the circuit interface jack 22, thereby enabling the circuit interface device 10 to perform data transmission with the electronic device 20.

In this embodiment, the connecting portion 116 and the circuit interface jack 22 conform to the USB interface specification. The USB specification defines two kinds of plugs with different sizes and shapes: one is Series A Plug and the other is Series B Plug.

In this embodiment, the connecting portion 116 adopts the specification of Series A Plug, and has a flat rectangular shape with the dimension of 15.7 mm in length, 7.5 mm in width, and 12 mm in height. Here, the connecting portion 116 is used for being connected to the circuit interface jack 22 of the same specification.

Besides, the shell body 110 may further have a baffle 122, and the baffle 122 is located at the same side surface of the shell body 110 as the socket 116a. When the circuit board assembly 200 is assembled in the shell body 110 via the opening 118a, one side of the circuit board assembly 200 is pressed against an inner side of the baffle 122, that is, when the circuit board assembly 200 slides into the first sliding slot 120 through the sliding block 222 to be positioned, the circuit board assembly 200 is urged by the baffle 122 to stop moving, so that the circuit board assembly 200 smoothly arrives and is positioned, thereby completing the assembly process.

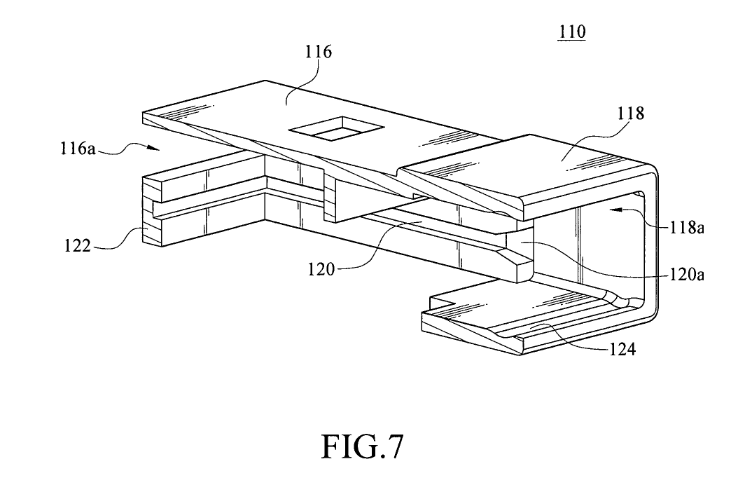

FIG. 6 is another schematic cross-sectional view of FIG. 3. FIG. 7 is another schematic three-dimensional cross-sectional view of FIG. 3. Referring to FIGS. 2, 6, and 7, the shell cover 130 has an accommodating portion 132. The accommodating portion 132 is disposed at the end portion 118 of the shell body 110, and has a second sliding slot 132a. The circuit board assembly 200 is slidably disposed in the second sliding slot 132a through the sliding block 222, so as to be accommodated in the shell cover 130.

Based on the above, two opposite side surfaces of the shell cover 130 respectively have a raised portion 134, and two side surfaces inside the shell body 110 corresponding to the shell cover 130 respectively have a depressed portion 124, which is adjacent to the opening 118a. The raised portions 134 of the shell cover 130 are clipped to the depressed portions 124 inside the shell body 110. Furthermore, when the shell cover 130 is assembled in the end portion 118 of the shell body 110 by enabling the accommodating portion 132 to pass through the opening 118a, the raised portions 134 on two side surfaces of the shell cover 130 are correspondingly clipped in the depressed portions 124, so that the shell cover 130 is securely combined with the end portion 118 of the shell body 110, thereby preventing the shell cover 130 from sliding inside the shell body 110 or even falling off.

In addition, since a lot of electronic components 214 are arranged on the circuit board 210, the circuit board protection cap 220 further has an accommodating space 228. When the circuit board 210 and the circuit board protection cap 220 are combined together, an accommodating space 228 is formed between one side surface of the circuit board 210 and the circuit board protection cap 220. The accommodating space 228 is used for accommodating the electronic components 214 on one side of the circuit board 210. In this way, not only the electronic components 214 between the side surface of the circuit board 210 and the circuit board protection cap 220 are protected, but also the electronic components 214 are enabled to be placed on two side surfaces of the circuit board 210, so that the circuit board 210 is shortened, and the overall volume of the circuit interface device 10 is reduced.

In order to smoothly assemble the circuit board assembly 200 into the shell body 110, one end of the first sliding slot 120 may have a guide section 120a, for example, a guide angle. The guide section 120a increases the width of one end of the first sliding slot 120, so that the sliding block 222 of the circuit board protection cap 220 can easily slide into the first sliding slot 120 through the guide section 120a, so as to facilitate the assembly process.

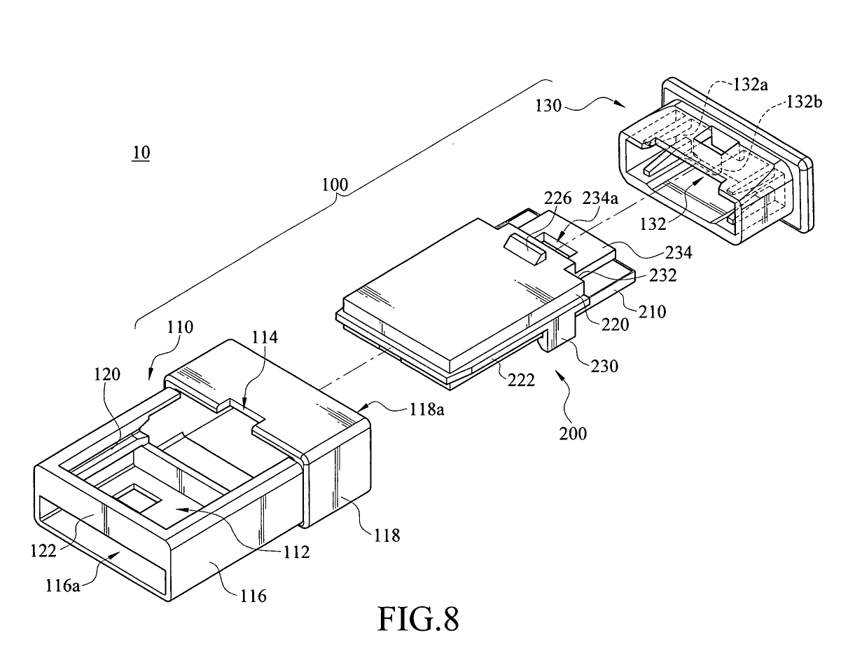

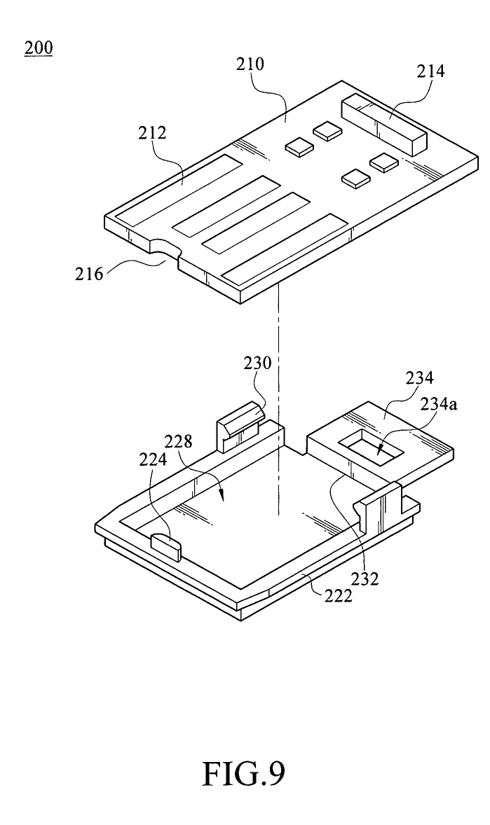

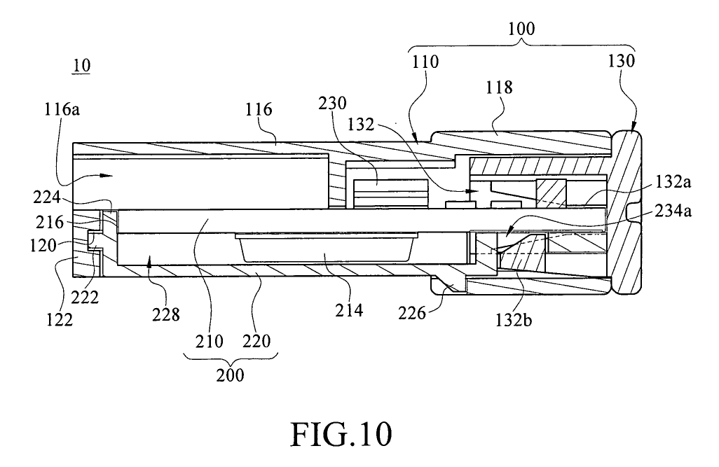

FIGS. 8 to 10 are schematic views of a circuit interface device according to another embodiment of the present invention. A part of members in this embodiment are substantially the same as that of the first embodiment, and like reference numerals indicate like elements. Referring to FIGS. 8, 9, and 10, a circuit interface device 10 in this embodiment comprises a shell 100 and a circuit board assembly 200. The shell 100 comprises a shell body 110 and a shell cover 130. The circuit board assembly 200 is formed by a circuit board 210 and a circuit board protection cap 220. The circuit board assembly 200 is accommodated in the shell body 110. The shell cover 130 has an accommodating portion 132, and the shell cover 130 is assembled in the shell body 110 through the accommodating portion 132.

The circuit board protection cap 220 in this embodiment further has two hooks 230 located at two opposite sides thereof, so as to fix the circuit board 210 on the circuit board protection cap 220. When the circuit board 210 is assembled on the circuit board protection cap 220, first, two side edges of the circuit board 210 press the hooks 230 from slanting surfaces on top of the hooks 230, such that the hooks 230 are elastically deformed and expanded outwards, and then, after the circuit board 210 is clipped, the hooks 230 restore the original positions to tightly fix the circuit board 210 on the circuit board protection cap 220.

The circuit board assembly in this embodiment not only utilizes the matching mode between the first positioning portion 216 of the circuit board 210 and the second positioning portion 224 of the circuit board protection cap 220, but also clips the circuit board 210 on the circuit board protection cap 220 by using the hooks 230, so as to increase the tightness between the circuit board 210 and the circuit board protection cap 220. It should be noted that, the present invention is not limited to using the hooks 230 to fix the circuit board 210 on the circuit board protection cap 220, and other combining forms may also be used.

In addition, one end of the circuit board protection cap 220 is a combining end 232. A snapping member 234 is extended from the combining end 232, and the snapping member 234 has a hole 234a. A slanting block 132b is disposed at a position of the accommodating portion 132 corresponding to the hole 234a, and the slanting block 132b is embedded in the hole 234a, so that the circuit board protection cap 220 is combined with the shell cover 130. In particular, when the shell cover 130 is assembled in the shell body 110, by embedding the slanting block 132b of the accommodating portion 132 into the hole 234a of the snapping member 234, the circuit board protection cap 220 and the shell cover 130 are tightly combined, so as to combine the circuit board assembly 200 with the shell cover 130. Moreover, since the circuit board assembly 200 is fixed in the shell body 110, the shell cover 130 is indirectly combined with the shell body 110.

In view of the above, the circuit interface device in the present invention can be easily and securely assembled in a structural matching mode, so that a stable structural strength is maintained, and the labor time is effectively reduced during assembly, thereby facilitating the assembly process. Moreover, the circuit board protection cap and the circuit board in the present invention are combined as the circuit board assembly, and the circuit board is supported by the circuit board protection cap, so that the electrical connection contacts on the circuit board are corresponding to the socket, thereby increasing the structural strength of the circuit interface device and enabling the circuit interface device to be stably inserted into the circuit interface jack. Since one side of the circuit board protection cap may serve as the outer side surface of the shell body, the circuit board protection cap can adopt different materials and colors to change the appearance of the circuit interface device. Furthermore, the present invention shortens the circuit board by using the configuration of a double-layer circuit board, and thus has the advantage of a reduced volume.

What is claimed is:

1. A circuit interface device, applicable to an electronic device having a circuit interface jack, the circuit interface device comprising:
a shell, having a socket disposed at one end thereof; and
a circuit board assembly, having a circuit board and a circuit board protection cap, wherein the circuit board is disposed on the circuit board protection cap, a plurality of electronic components is arranged on two surfaces of the circuit board, and a plurality of electrical connection contacts is disposed on one side surface of the circuit board;
wherein the circuit board assembly is assembled in the shell, the circuit board protection cap enables the electrical connection contacts of the circuit board to be corresponding to the socket, and the shell constitutes a connecting portion, and enables the circuit interface device to be inserted into the circuit interface jack through the connecting portion.

2. The circuit interface device according to claim 1, wherein the shell comprises a shell body and a shell cover, the shell body comprises the connecting portion and an end portion, the socket is disposed at one side of the connecting portion, the end portion is opened with an opening, and the shell cover has an accommodating portion, and passes through the opening with the accommodating portion.

3. The circuit interface device according to claim 1, wherein the connecting portion and the circuit interface jack conform to a universal serial bus (USB) interface specification.

4. The circuit interface device according to claim 1, wherein the circuit board has a first positioning portion, the circuit board protection cap has a second positioning portion, and the first positioning portion and the second positioning portion match each other to fix the circuit board on the circuit board protection cap.

5. The circuit interface device according to claim 1, wherein the circuit board protection cap has an accommodating space for accommodating the electronic components of the circuit board.

6. The circuit interface device according to claim 1, wherein the circuit board protection cap further has two hooks located at two opposite sides thereof, so as to fix the circuit board on the circuit board protection cap.

7. The circuit interface device according to claim 2, wherein the circuit board protection cap has a sliding block disposed on a side edge thereof, the shell body has a first sliding slot disposed on an inner side surface thereof, and the circuit board protection cap is slidably disposed in the first sliding slot through the sliding block and disposed in the shell body.

8. The circuit interface device according to claim 2, wherein the accommodating portion has a second sliding slot, and the circuit board assembly is slidably disposed in the second sliding slot through the sliding block.

9. The circuit interface device according to claim 2, wherein one end of the circuit board protection cap is a combining end, a snapping member is extended from the combining end, the snapping member has a hole, and a slanting block is disposed at a position of the accommodating portion corresponding to the hole, so as to be embedded in the hole.

10. The circuit interface device according to claim 2, wherein the shell body has a baffle located at the same side as the connecting portion, and one end of the circuit board assembly is pressed against the baffle.

11. The circuit interface device according to claim 2, wherein the shell body has a clipping slot disposed on one side surface thereof, the circuit board protection cap has a clipping block disposed on one side thereof corresponding to the clipping slot, and when the circuit board assembly is installed in the shell body, the clipping block and the clipping slot are clipped to each other.

12. A circuit interface device, comprising:
a shell body, having an opening formed at a first side thereof; and
a circuit board, having a circuit board protection cap on one side thereof;
wherein the shell body has an open slot formed at a second side thereof, the circuit board is inserted into the shell body through the opening, and the circuit board protection cap is positioned and exposed out of the shell body through the open slot.

13. The circuit interface device according to claim 12, wherein the shell body has a sliding slot disposed therein, and the circuit board is inserted in the sliding slot.

14. The circuit interface device according to claim 12, wherein the circuit board has a plurality of electrical connection contacts disposed on one side thereof and at least one electronic component is disposed on the circuit board in the circuit board protection cap.

15. The circuit interface device according to claims 12 to 14, wherein a shell cover is connected at the opening.
